(19) United States
(12) Patent Application Publication
(10) Pub. No.: US 2025/0133850 A1
(43) Pub. Date: Apr. 24, 2025

(54) SEMICONDUCTOR PACKAGE

(71) Applicant: Samsung Electronics Co., Ltd., Suwon-si (KR)

(72) Inventor: Sanguk KIM, Suwon-si (KR)

(73) Assignee: Samsung Electronics Co., Ltd., Suwon-si (KR)

(21) Appl. No.: 18/676,885

(22) Filed: May 29, 2024

(30) Foreign Application Priority Data
Oct. 20, 2023 (KR) 10-2023-0141145

(51) Int. Cl. H01L 27/146

(52) U.S. Cl. CPC H10F 39/8053; H10F 39/804; H10F 39/8063; H10F 39/811

(57) ABSTRACT

A semiconductor package includes a package substrate, an image sensor including a body portion on the package substrate, color filters on the body portion, microlenses respectively on the color filters, a light blocking filter pattern peripheral to the microlenses in a horizontal direction, a capping layer covering at least a portion of the light blocking filter pattern, an upper thin film covering at least a portion of the capping layer, and connection pads peripheral to the light blocking filter pattern in the horizontal direction, a glass cover on the image sensor, and an adhesive structure on the body portion spaced apart from the capping layer and the light blocking filter pattern in the horizontal direction, the adhesive structure covering at least a portion of the connection pads, between the image sensor and the glass cover.

### CROSS-REFERENCE TO RELATED APPLICATION(S)

This application claims benefit of priority to Korean Patent Application No. 10-2023-0141145 filed on Oct. 20, 2023 in the Korean Intellectual Property Office, the disclosure of which is incorporated herein by reference in its entirety.

### BACKGROUND

The present inventive concepts relate to a semiconductor package.

An image sensor is a semiconductor device converting an optical image into an electrical signal. Image sensors are used in general electronics for consumers such as digital cameras, cellphone cameras, and handheld camcorders, as well as cameras in automobiles, security devices, and robots. Such image sensors require implementation of miniaturization and high resolution. Thus, various studies have been conducted to mount an image sensor on a package.

### SUMMARY

Aspects of the present inventive concepts provide semiconductor packages having improved reliability.

According to aspects of the present inventive concepts, there is provided a semiconductor package including a package substrate, an image sensor including a body portion on the package substrate, color filters on the body portion, microlenses respectively on the color filters, a light blocking filter pattern peripheral to the microlenses in a horizontal direction, a capping layer covering at least a portion of the light blocking filter pattern, an upper thin film covering at least a portion of the capping layer, and connection pads peripheral to the light blocking filter pattern in the horizontal direction, a glass cover on the image sensor, and an adhesive structure on the body portion spaced apart from the capping layer and the light blocking filter pattern in the horizontal direction, the adhesive structure covering at least a portion of the connection pads, between the image sensor and the glass cover.

According to another aspect of the present inventive concepts, there is provided a semiconductor package including a package substrate, an image sensor on the package substrate, the image sensor having a first region and a second region peripheral to the first region in a horizontal direction, a glass cover on the image sensor, and an adhesive structure connecting the image sensor and the glass cover to each other. The image sensor may include a stack structure including a body portion, and a light blocking conductive layer and a protective layer stacked on the body portion, a light blocking filter pattern on the stack structure within the first region, a capping layer on the light blocking filter pattern, and an upper thin film on the stack structure. The adhesive structure may overlap at least a portion of each of the stack structure and the upper thin film in a vertical direction within the second region.

According to another aspect of the present inventive concepts, there is provided a semiconductor package including a package substrate, an image sensor on the package substrate, the image sensor including microlenses on a central portion thereof, a light blocking filter pattern peripheral to the microlenses in a horizontal direction, a capping layer surrounding at least a portion of the light blocking filter pattern, and an upper thin film surrounding at least a portion of the capping layer, a glass cover spaced apart from the image sensor in a vertical direction, and an adhesive structure between the image sensor and the glass cover, the adhesive structure having one side surface in contact with at least a portion of the upper thin film.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a top view of a semiconductor package according to some example embodiments of the present inventive concepts;

FIG. 2A is a cross-sectional view of a semiconductor package according to some example embodiments of the present inventive concepts, taken along line I-I′ of FIG. 1, and FIG. 2B is a partially enlarged view of a region corresponding to region “A” of FIG. 2A;

FIG. 3A is a cross-sectional view of a semiconductor package according to some example embodiments of the present inventive concepts, taken along line I-I′ of FIG. 1, and FIG. 3B is a partially enlarged view of a region corresponding to region “A” of FIG. 3A; and

FIGS. 4 to 7 are cross-sectional views of main processes of a method of manufacturing a semiconductor package according to some example embodiments of the present inventive concepts.

### DETAILED DESCRIPTION

Hereinafter, example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which a component is actually arranged.

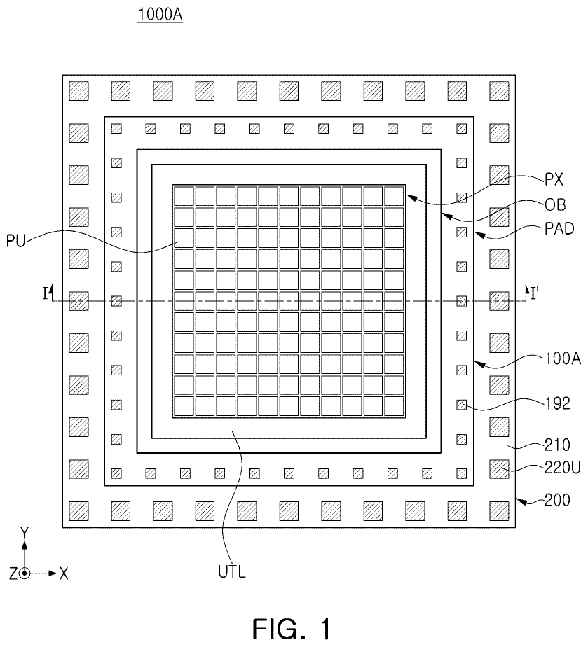

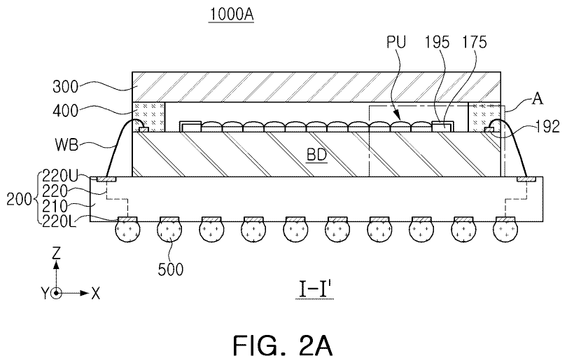

FIG. 1 illustrates a schematic plan arrangement of a semiconductor package 1000A according to an some example embodiments of the present inventive concepts, FIG. 2A is a cross-sectional view of the semiconductor package 1000A according to some example embodiments of the present inventive concept, taken along line I-I′ of FIG. 1, and FIG. 2B is a partially enlarged view of a region corresponding to region “A” of FIG. 2A.

Referring to FIGS. 1, 2A, and 2B, the semiconductor package 1000A of some example embodiments may include a package substrate 200, an image sensor 100A, a glass cover 300, and an adhesive structure 400. In addition, the semiconductor package 1000A may further include a plurality of connection bumps 500 disposed on a lower portion of the package substrate 200.

The package substrate 200 may include an insulating layer 210, an interconnection layer 220, and interconnection pads 220U. The package substrate 200 may further include a via structure electrically connecting interconnection layers 220, positioned on different levels, to each other. The package substrate 200 may be a semiconductor package substrate including a printed circuit board (PCB), a ceramic substrate, a glass substrate, or a tape interconnection substrate.

The insulating layer 210 may include an insulating resin. The insulating resin may include a thermosetting resin such as an epoxy resin, a thermoplastic resin such as polyimide, or a resin in which in which such resins are impregnated with an inorganic filler, for example, a prepreg, an Ajinomoto build-up film (ABF), FR-4, or bismaleimide triazine (BT). The insulating resin may include a photosensitive resin such as a photoimageable dielectric (PID). For example, when the package substrate 200 is a PCB substrate, the insulating layer 210 may be a core insulating layer (for example, a prepreg) of a copper clad laminate. The insulating layer 210 may have a form in which a large number of insulating layers are stacked in a vertical direction (Z-direction), and first insulating layers on different levels may have unclear boundaries therebetween, depending on the process.

The interconnection layer 220 may be disposed within the insulating layer 210, and may form an electrical path within the package substrate 200. The interconnection layer 220 may be formed of at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C). The interconnection layer 220 may be provided as a plurality of layers.

On the insulating layer 210, a plurality of interconnection pads 220U may be disposed around the image sensor 100A, and may be electrically connected to the image sensor 100A. The plurality of interconnection pads 220U may be electrically connected to corresponding connection pads 192 of the image sensor 100A through a connection wire WB. FIG. 1 illustrates a schematic plan arrangement of the semiconductor package 1000A according to some example embodiments, and may be illustrated with the connection wire WB omitted.

The image sensor 100A may have a pixel region PX, an optical black region OB disposed on the outside of the pixel region PX, and a pad region PAD disposed on the outside of the optical black region OB. For example, the optical black region OB may be peripheral to the pixel region PX in a horizontal direction (for example, an X-axis direction) and the pad region may be peripheral to the optical black region OB in a horizontal direction (for example, an X-axis direction). The image sensor 100A may have the pixel region PX including an active pixel for generating active signals corresponding to wavelengths of external light, the optical black region OB including an optical black pixel for generating an optical black signal due to blocked external light, the pad region PAD for exchanging electrical signals with an external device. In the image sensor 100A, the pixel region PX, the optical black region OB, and the pad region PAD, illustrated in FIG. 1, may form a single upper chip structure including the second substrate 101. A lower chip structure including a peripheral circuit region may be coupled to a lower portion of the upper chip structure. Such a configuration will be described in more detail below with reference to FIGS. 2A and 2B. However, in some example embodiments, the image sensor 100A may not further include the lower chip structure, and may further include a peripheral circuit region, disposed on the outside of the pixel region PX.

The pixel region PX may include a plurality of unit pixels PU arranged in a matrix form. Each of the plurality of unit pixels PU may include a photoelectric conversion device. In some example embodiments, a dummy pixel region may be further disposed on the outside of the pixel region PX.

The optical black region OB may be disposed on the outside of the pixel region PX, and may be disposed to surround at least a portion of the pixel region PX or the entire pixel region PX, as illustrated in FIG. 1. The optical black region OB, an optical black pixel used to measure dark current, may include unit pixels PU.

The pad region PAD may be positioned along an end of the second substrate 101 on the outside of the pixel region PX and the optical black region OB. The pad region PAD may include input/output pads PL for transmitting and receiving electrical signals to and from an external device. In some example embodiments, the input/output pads PL may serve to transmit driving power, such as an externally supplied power voltage or ground voltage, to circuits disposed in the peripheral circuit region of the image sensor 100A.

Referring to FIGS. 2A and 2B, the image sensor 100A may include a first chip structure S1 and a second chip structure S2, stacked in a direction, for example, Z-direction. The first chip structure S1 may have a circuit region for driving the unit pixels PU of the pixel region PX, and the second chip structure S2 may have a pixel region PX, an optical black region OB, and a pad region PAD.

In some example embodiments, the image sensor 100A may further include a memory chip electrically connected to the circuit region of the first chip structure S1 to transmit and receive image data. In addition, in some example embodiments, the image sensor 100A may not necessarily include the first chip structure S1 and the second chip structure S2, and the first chip structure S1 may be omitted. In this case, the circuit region for driving the unit pixels PU may be disposed on the outside of a pixel region PX of a second substrate 101.

The first chip structure S1 may include a first substrate 10, circuit devices 20, a first interconnection structure 30, and a first insulating layer 40.

The first substrate 10 may be a semiconductor substrate. The first substrate 10 may include, for example, a semiconductor material, such as a Group IV semiconductor. For example, the Group IV semiconductor may include silicon, germanium, or silicon-germanium. The first substrate 10 may be provided as a bulk wafer, an epitaxial layer, an epitaxial layer, a silicon on insulator (SOI) layer, or a semiconductor on insulator (SeOI) layer. The first substrate 10 may have impurity regions 12.

The circuit devices 20 may include a gate electrode layer, a gate insulating layer, and circuit transistors having a source/drain region within the impurity regions 12. The circuit devices 20 may provide a constant signal to unit pixels PU of the second chip structure S2 or control an output signal from each unit pixel PU.

The first interconnection structure 30 may be an interconnection structure electrically connected to the circuit devices 20. The first interconnection structure 30 may include interconnection lines and contact plugs. The number of layers of the interconnection lines within the first interconnection structure 30, and the number and arrangements of the interconnection lines and the contact plugs may be changed in various manners in some example embodiments. The first interconnection structure 30 may be formed of a conductive material, for example, at least one of tungsten (W), copper (Cu), aluminum (Al), gold (Au), silver (Ag), and/or alloys thereof.

The first insulating layer 40 may be formed of an insulating material, and may include one or a plurality of layers. For example, the first insulating layer 40 may include silicon oxide and/or silicon nitride. The first insulating layer 40 may be disposed to a predetermined thickness from an upper surface thereof, and may further include a bonding layer for bonding to the second chip structure S2. The bonding layer may be formed of an insulating material, and may include, for example, at least one of SiO, SiN, SiCN, SiOC, SiON, and/or SiOCN.

The second chip structure S2 may be disposed on the first chip structure S1, and may be electrically connected to the first chip structure S1. The second chip structure S2 may include a second substrate 101, a second interconnection structure 130, a second insulating layer 140, and a third insulating layer 150. The second chip structure S2 may functionally have a pixel region PX, an optical black region OB, and a pad region PAD.

The second substrate 101 may have a first surface 101F, opposing the first chip structure S1, and a second surface 101S, opposing the first surface 101F. In the second substrate 101, the pixel region PX, the optical black region OB, and the pad region PAD may be defined. The second substrate 101 may be a semiconductor substrate. For example, the second substrate 101 may be formed of a P-type silicon substrate. In some example embodiments, the second substrate 101 may include a P-type bulk substrate and a P-type or N-type epitaxial layer grown thereon. Alternatively, the second substrate 101 may include an N-type bulk substrate and a P-type or N-type epitaxial layer grown thereon. In some example embodiments, the second substrate 101 may be formed of an organic plastic substrate. For example, the image sensor 100A may be a backside illumination-type CMOS image sensor in which light is incident on the second surface 101S of the second substrate 101.

The second interconnection structure 130, along with the second insulating layer 140, may be disposed between the first surface 101F of the second substrate 101 and the first chip structure S1. The second interconnection structure 130 may be an interconnection structure electrically connected to components within and on the second substrate 101. The second interconnection structure 130 may include interconnection lines and contact plugs. The number of layers of the interconnection lines within the second interconnection structure 130, and the number and arrangements of the interconnection lines and the contact plugs may be changed in various manners in some example embodiments. The second interconnection structure 130 may be formed of a conductive material, for example, at least one of tungsten (W), copper (Cu), aluminum (Al), gold (Au), silver (Ag), and/or alloys thereof.

The second insulating layer 140 may be formed of an insulating material, and may include one or a plurality of layers. For example, the second insulating layer 140 may include silicon oxide and/or silicon nitride. In a similar manner to the first insulating layer 40, the second insulating layer 140 may be disposed to a predetermined thickness from a lower surface thereof, and may further include a bonding layer for bonding to the first chip structure S1.

As illustrated, the third insulating layer 150 may include a plurality of layers sequentially stacked on the second surface 101S of the second substrate 101, but the present inventive concept is not limited thereto. For example, the third insulating layer 150 may include at least two of an aluminum oxide layer, a hafnium oxide layer, a tantalum oxide layer, a zirconium oxide layer, a silicon oxynitride layer, a silicon oxide layer, and/or a silicon nitride layer. In some example embodiments, the third insulating layer 150 may include a fixed charge layer and/or an anti-reflection layer. The anti-reflection layer may be provided to adjust refractive index such that incident light proceeds to the photoelectric conversion device 105 with high transmittance.

Referring to FIG. 2B, the pixel region PX may further include photoelectric conversion devices 105, device isolation regions 107, and pixel isolation regions 110 disposed within the second substrate 101, pixel devices 120 disposed within the second insulating layer 140, grid layers 160, color filters 170, and microlenses 190 disposed on an upper portion of the second substrate 101. A region of the image sensor 100A including a lower chip structure S1, the second insulating layer 140, the second substrate 101, and the third insulating layer 150 may be referred to as a body portion BD. It may be understood that the grid layers 160, the color filters 170, and the microlenses 190, disposed on the upper portion of the second substrate 101, are disposed on an upper portion of the body portion BD of the image sensor 100A.

The photoelectric conversion devices 105 may be disposed within the second substrate 101, and may absorb incident light to generate and accumulate charges corresponding to an amount of light. The photoelectric conversion devices 105 may include at least one of a photodiode, a phototransistor, a photogate, a pinned photodiode (PPD), and/or combinations thereof. When the photoelectric conversion devices 105 include a photodiode, the photoelectric conversion devices 105 may have an impurity region having a conductivity type different from that of the second substrate 101, and may form a PN junction to a well region within the second substrate 101.

The device isolation regions 107 include an insulating material, and may be disposed within the second substrate 101 to a predetermined depth from the first surface 101F of the second substrate 101.

The pixel isolation regions 110 may be disposed within the second substrate 101 below a boundary of each unit pixel PU. Lower surfaces of the pixel isolation regions 110 may be connected to the device isolation regions 107. However, in some example embodiments, arrangements of the pixel isolation regions 110 within the second substrate 101 in a Z-direction may be changed in various manners. The pixel isolation regions 110 may be disposed to surround the photoelectric conversion devices 105. However, a relative arrangement relationship between the pixel isolation regions 110 and the photoelectric conversion devices 105 is not limited to that illustrated, and may be changed in various manners. For example, lower surfaces of the pixel isolation regions 110 may be positioned to be higher or lower than lower surfaces of the photoelectric conversion devices 105. The pixel isolation regions 110 may include an insulating material or a conductive material. For example, when the pixel isolation regions 110 include a conductive material. The pixel isolation regions 110 may further include an insulating layer disposed between the pixel isolation regions 110 and the second substrate 101.

The pixel devices 120 may be disposed between the photoelectric conversion devices 105 and the second interconnection structure 130. The pixel devices 120 may be included in a pixel circuit of a unit pixel PU. For example, the pixel devices 120 may include a transfer gate forming a transfer transistor, as illustrated in FIG. 2B. The transfer gate may be a vertical transistor gate including a portion extending from the first surface 101F of the second substrate 101 into the second substrate 101. In addition to the transfer gate, the pixel devices 120 may further include a floating diffusion region (not illustrated) within the second substrate 101 and gates on the first surface 101F of the second substrate 101. The gates may be included in a source follower transistor, a reset transistor, and a select transistor.

On the third insulating layer 150, the grid layers 160 may be disposed between the color filters 170 to isolate the color filters 170 from each other. The grid layers 160 may be disposed on the third insulating layer 150, and may be disposed below a boundary of each unit pixel PU. The grid layers 160 may be disposed on upper portions of the pixel isolation regions 110 in the Z-direction, perpendicular to one surface of the second substrate 101. The grid layers 160 may include first and second grid layers 162 and 164 sequentially stacked from the bottom. The first grid layer 162 may be, for example, a barrier metal layer, and may include a metal material. The first grid layer 162 may include, for example, at least one of titanium (Ti), titanium oxide, tantalum (Ta), and tantalum oxide. The second grid layer 164 may be an insulating layer, a low refractive index (LRI) layer. The second grid layer 164 may include an insulating material, for example, an oxide or nitride including silicon (Si), aluminum (Al), or a combination thereof. For example, the second grid layer 164 may include silicon oxide having a porous structure or silica nanoparticles having a network structure. In some example embodiments, a protective layer, covering upper and side surfaces of the grid layers 160 and extending onto the third insulating layer 150, may be further disposed.

The color filters 170 may be disposed on the third insulating layer 150 and the grid layers 160 on upper portions of the photoelectric conversion devices 105. The color filters 170 may allow light having a specific wavelength to pass therethrough and reach the photoelectric conversion devices 105 there below. The color filters 170 may be implemented as a color filter array including a red (R) filter, a green (G) filter, and a blue (B) filter. The color filter 170 may be formed of, for example, a material obtained by mixing a resin with a pigment including a metal or metal oxide.

The microlenses 190 may be disposed on the color filters 170, and may change a path of light incident on a region other than the photoelectric conversion devices 105 to converge light into the photoelectric conversion devices 105. The microlenses 190 may be formed of a transparent photoresist material or a transparent thermosetting resin film. For example, the microlenses 190 may be formed of a TMR series resin (produced by Tokyo Ohka Kogo, Co., Ltd.) or an MFR series resin (produced by Japan Synthetic Rubber Corporation).

Referring to FIG. 2B, the optical black region OB may further include a photoelectric conversion device 105, device isolation regions 107, and pixel isolation regions 110 disposed within the second substrate 101, and a light blocking conductive layer 180a, a protective layer 185, a light blocking filter pattern 175, and a capping layer 195 disposed on an upper portion of the second substrate 101. The optical black region OB may be used to remove a noise signal caused by dark current. Hereinafter, descriptions overlapping those described above with reference to the pixel region PX will be omitted. The optical black region OB may be referred to as a first region.

The photoelectric conversion device 105 may be disposed within the second substrate 101 in a portion of the optical black region OB. In the optical black region OB, a region including the photoelectric conversion device 105 may provide a reference for noise caused by the photoelectric conversion device 105. In the optical black region OB, a region in which the photoelectric conversion device 105 is not disposed may provide a reference for process noise caused by factors other than the photoelectric conversion device 105.

The light blocking conductive layer 180a and the light blocking filter pattern 175 may be included in a light blocking pattern blocking light, and may block light from entering the second substrate 101 there below. The light blocking conductive layer 180a may include, for example, a metal material. The light blocking conductive layer 180a may include, for example, at least one of tungsten (W), titanium (Ti), copper (Cu), aluminum (Al), gold (Au), silver (Ag), and/or alloys thereof. The light blocking filter pattern 175 may include, for example, a blue (B) filter. The light blocking filter pattern 175 may be formed of a material the same as that of the color filters 170 described above, but the present inventive concepts are not limited thereto.

The protective layer 185 may be disposed on the light blocking conductive layer 180a. The protective layer 185 may be disposed within the optical black region OB, and may extend to the pad region PAD. The protective layer 185 may include, for example, metal oxide. In some example embodiments, the protective layer 185 may include aluminum oxide (Al₂O₃), but the present inventive concepts are not limited thereto. The light blocking conductive layer 180a and the protective layer 185, layers stacked on the body portion BD of the image sensor 100A, may be referred to as a stack structure.

The light blocking filter pattern 175 may be disposed on the stack structure within the optical black region OB. The light blocking filter pattern 175 may be disposed on the outside of the microlenses 190, for example the light blocking filter pattern 175 may be adjacent the microlenses 190. In some example embodiments, the light blocking filter pattern 175 may be disposed within the optical black region OB to be adjacent to the pixel region PX. The light blocking filter pattern 175 may be disposed to be in contact with the color filters 170. For example, the optical black region OB may be peripheral to the pixel region PX such that the light blocking filter pattern 175 may be peripheral to the microlenses 190 in a horizontal direction (for example, an X-axis direction).

The capping layer 195 may be disposed on the light blocking filter pattern 175 to cover at least a portion of the light blocking filter pattern 175. In some example embodiments, the capping layer 195 may cover a side surface, adjacent to the adhesive structure 400, among side surfaces of the light blocking filter pattern 175, but the present inventive concepts are not limited thereto. The capping layer 195 may include a transparent photoresist material or a transparent thermosetting resin material. The capping layer 195 may be a material layer, formed in the optical black region OB, during a deposition process for forming the microlenses 190 of the pixel region PX. Accordingly, the capping layer 195 may include a material the same as that of the microlenses 190. The light blocking filter pattern 175 and the capping layer 195 may include a material having a thermal expansion coefficient higher than that of silicon (Si).

An upper thin film UTL may be disposed on the capping layer, within the optical black region OB, and may extend to the pad region PAD. The upper thin film UTL may be disposed on the capping layer 195 to cover at least a portion of the capping layer 195. In some example embodiment, the upper thin film UTL may cover a side surface, adjacent to the adhesive structure 400, among side surfaces of the capping layer 195, but the present inventive concept is not limited thereto. The upper thin film UTL may be disposed on a stack structure, and at least a portion of the upper thin film UTL may be in contact with the stack structure. The upper thin film UTL may be disposed to surround a buffer layer 157 and connection pads 192 in plan view. In some example embodiments, the upper thin film UTL may extend onto the microlenses 190, but the present inventive concepts are not limited thereto.

Referring to FIG. 2B, the pad region PAD may further include a connection via VIA including a via conductive layer 180b and a via filling layer 155, a buffer layer 157 on the connection via VIA, a via isolation region TI, an input/output pad PL, and a capping layer 195. The pad region PAD may be referred to as a second region.

The connection via VIA may extend in the vertical direction (for example, Z-axis direction) from an upper surface of the body portion BD to a lower surface of the body portion BD. The connection via VIA may electrically connect the connection pad 192 and the first chip structure S1 to each other. An upper portion of the connection via VIA may be connected to the connection pad 192 by the via conductive layer 180b, and a lower portion of the connection via VIA may pass through the third insulating layer 150, the second substrate 101, and the second insulating layer 140 to be connected to the first interconnection structure 30 of the first chip structure S1. The connection via VIA may have a cylindrical shape, but the present inventive concepts are not limited thereto. In some example embodiments, the connection via VIA may have a shape having a downwardly decreasing width.

The via conductive layer 180b may be disposed to cover a sidewall and a bottom surface of the connection via VIA. The via conductive layer 180b may be formed in a process operation the same as that of the light blocking conductive layer 180a of the optical black region OB, and thus may include a material the same as that of the light blocking conductive layer 180a of the optical black region OB. The via conductive layer 180b may be formed of a conductive material, for example, at least one of tungsten (W), copper (Cu), aluminum (Al), gold (Au), silver (Ag), and/or alloys thereof. The via filling layer 155 may be disposed on the via conductive layer 180b to fill the connection via VIA, and may have a concave upper surface. The via filling layer 155 may include an insulating material, but the present inventive concepts are not limited thereto.

The buffer layer 157 may be disposed to cover the concave upper surface of the via filling layer 155. The buffer layer 157 may include, for example, a cured photoresist material. However, in some example embodiments, the buffer layer 157 may be omitted.

The light blocking filter pattern 175 and the capping layer 195 may be disposed to extend from the optical black region OB.

The via isolation region TI may be positioned on at least one side of the connection via VIA, and a partial layer of the third insulating layer 150 may extend into the second substrate 101. The via isolation region TI may extend in the Z-direction within the second substrate 101.

The connection pad 192 may include an region in which the via conductive layer 180b extends and a pad conductive layer 191 on the via conductive layer 180b. The connection pad 192 may be an region electrically connected to an external device using wire bonding or the like. The pad conductive layer 191 may include a conductive material such as a metal material.

The glass cover 300 may be disposed on the image sensor 100A. The glass cover 300 may serve to physically protect an upper surface of the body portion BD and the microlenses 190 disposed on an upper portion of the body portion BD. The glass cover 300 may have an area the same as an area of the image sensor 100A, but the present inventive concepts are not limited thereto, and the glass cover 300 may have a larger area so as to protect the image sensor 100A.

The adhesive structure 400 may be disposed between the image sensor 100A and the glass cover 300. The adhesive structure 400 may be disposed within the pad region PAD to cover at least a portion of each of the connection pads 192 and connection wires WB, electrically connected to the connection pads 192, but the present inventive concept is not limited thereto, and may be disposed within at least a portion of the optical black region OB. The adhesive structure 400 may attach the glass cover 300 to the image sensor 100A. The adhesive structure 400 may be, for example, a film layer formed of a die-attach film (DAF). The adhesive structure 400 may be disposed on the body portion BD, and an uppermost end of the adhesive structure 400 may be positioned on a level higher than those of an upper end of the upper thin film UTL and upper ends of the microlenses 190. Upper portions of the upper thin film UTL and the microlenses 190 may have a space, spaced apart from the glass cover 300 in the vertical direction (for example, Z-axis direction).

The adhesive structure 400 may be disposed to be spaced apart from the light blocking filter pattern 175 and the capping layer 195 in a horizontal direction (for example, X-axis direction). The adhesive structure 400 may be disposed so as not to overlap the light blocking filter pattern 175 and the capping layer 195 in the vertical direction (for example, Z-axis direction). The adhesive structure 400 may be disposed to surround the light blocking filter pattern 175 and the capping layer 195 in plan view. The adhesive structure 400 may be disposed on a stack structure 180a and 185 and the upper thin film UTL. The adhesive structure 400 may overlap at least a portion of each of the stack structure 180a and 185 and the upper thin film UTL in the vertical direction (for example, Z-axis direction). The light blocking conductive layer 180a, the protective layer 185, the upper thin film UTL, and the adhesive structure 400 may be sequentially stacked on at least a portion of the body portion BD of the image sensor 100A from the bottom, for example, stacked sequentially in a direction away from the body portion BD of the image sensor 100A. A structure may be introduced in which the light blocking filter pattern 175 and the capping layer 195, including a material having a relatively high thermal expansion coefficient, are spaced apart from the adhesive structure 400 in the horizontal direction, thereby preventing or reducing in likelihood cracks from occurring on the upper thin film UTL due to a difference in thermal expansion coefficient.

A plurality of connection bumps 500 may be in the form of a land, ball, or pin. The plurality of connection bumps 500 may include, for example, tin (Sn) or an alloy (for example, Sn-Ag-Cu) including tin (Sn). The plurality of connection bumps 500 may be electrically connected to an interconnection layer 220 of a package substrate 200, and may be electrically connected to an external device such as a module substrate, a system board, or the like.

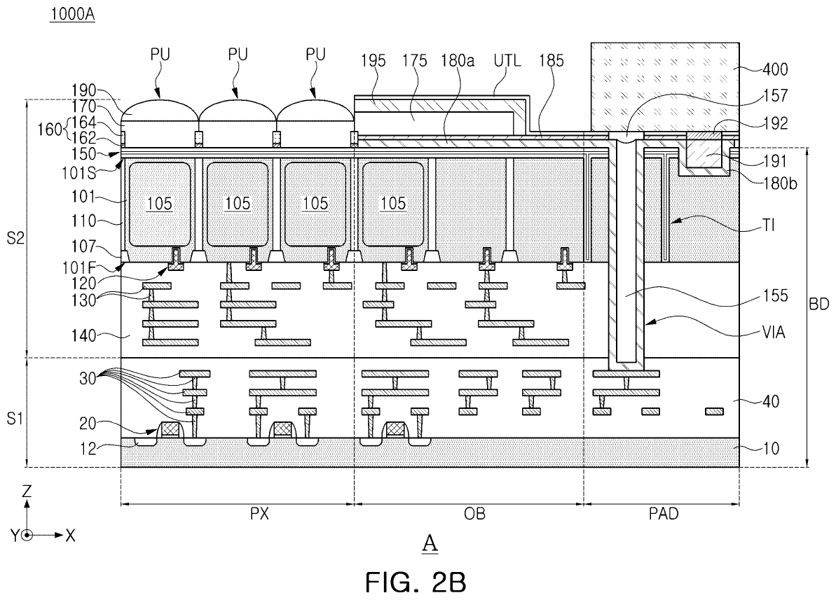

FIG. 3A is a cross-sectional view of a semiconductor package 1000B according to some example embodiments of the present inventive concepts, taken along line I-I′ of FIG. 1, and FIG. 3B is a partially enlarged view of a region corresponding to region “A” of FIG. 3A.

Referring to FIGS. 3A and 3B, the semiconductor package 1000B according to some example embodiments may be features the same as or similar to those described with reference to FIGS. 1 to 2B, except that a light blocking filter pattern 175 and a capping layer 195 extend in a horizontal direction. The light blocking filter pattern 175 may be disposed within an optical black region OB, and the capping layer 195 may be disposed to cover at least a portion of a side surface, adjacent to an adhesive structure 400, among side surfaces of the light blocking filter pattern 175. At least a portion of the capping layer 195 may extend to a pad region PAD. An upper thin film UTL may be disposed to cover at least a portion of the capping layer 195. The upper thin film UTL may cover a side surface, adjacent to the adhesive structure 400, among side surfaces of the capping layer 195. At least a portion of the upper thin film UTL may be disposed between the capping layer 195 and the adhesive structure 400. The light blocking filter pattern 175 and the capping layer 195 may be disposed on the body portion BD such that no space is present between the adhesive structures 400. The light blocking filter pattern 175 and the capping layer 195 may be in contact with the adhesive structure 400 with the upper thin film UTL interposed therebetween.

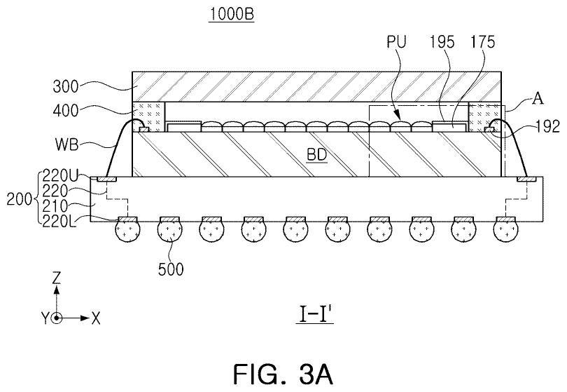

FIGS. 4 to 7 are cross-sectional views of main processes of a method of manufacturing a semiconductor package 1000A according to some example embodiments of the present inventive concepts.

Referring to FIG. 4, an image sensor 100A including unit pixels PU, the image sensor 100A having a body portion BD on which a light blocking filter pattern 175 and a capping layer 195 are disposed may be prepared.

The unit pixels PU may be disposed on a central portion of the image sensor 100A. Photoelectric conversion devices 105 may be disposed within the body portion BD, and color filters 170 and microlenses 190 may be disposed on the body portion BD to respectively correspond to the photoelectric conversion devices 105. The color filters 170 and microlenses 190 may be disposed on a level higher than that of an upper surface of the body portion BD, and may be disposed within a pixel region PX, among regions within the image sensor 100A. The light blocking filter pattern 175 and the capping layer 195 may be disposed on the outside of the unit pixels PU to surround the unit pixels PU. The light blocking filter pattern 175 and the capping layer 195 may be disposed within an optical black region OB, positioned on the outside of the pixel region PX. Connection pads 192 may be disposed on the outside of the body BD to be adjacent to a side surface of the body BD. In some example embodiments, the connection pads 192 may be disposed within a pad region PAD, positioned on the outside of the optical black region OB. For example, the pad region PAD may be peripheral to the optical black region OB in a horizontal direction (for example, an X-axis direction). The light blocking filter pattern 175 and the capping layer 195 may be disposed to be spaced apart from the connection pads 192 in a horizontal direction (for example, an X-axis direction).

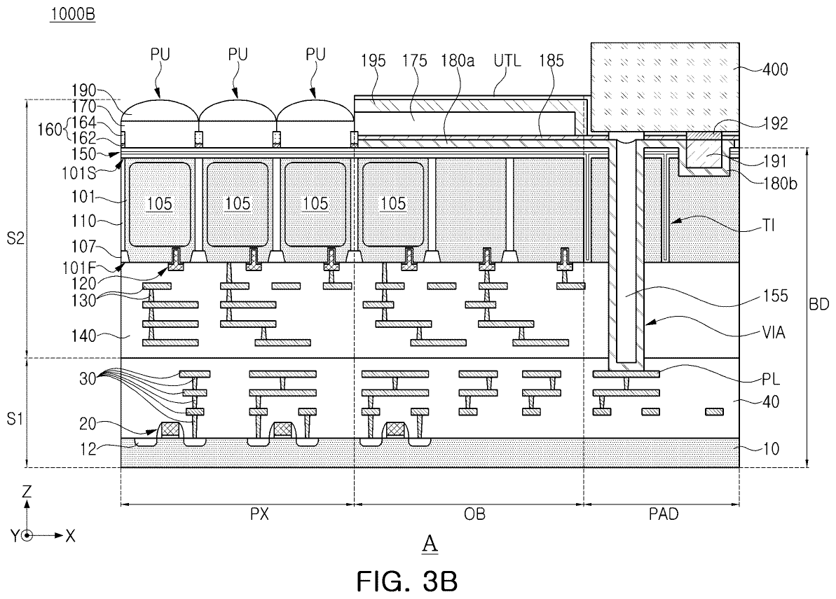

Referring to FIG. 5, the image sensor 100A may be mounted on a package substrate 200.

The image sensor 100A may be disposed such that a lower surface of the body portion BD is in contact with an upper surface of the package substrate 200. Interconnection pads 220U may be disposed to be adjacent to an outermost edge of the package substrate 200. The interconnection pads 220U may be disposed to surround the body portion BD in plan view. The connection pads 192 of the image sensor 100A may be electrically connected to corresponding interconnection pads 220U of the package substrate 200 through connection wires WB, respectively.

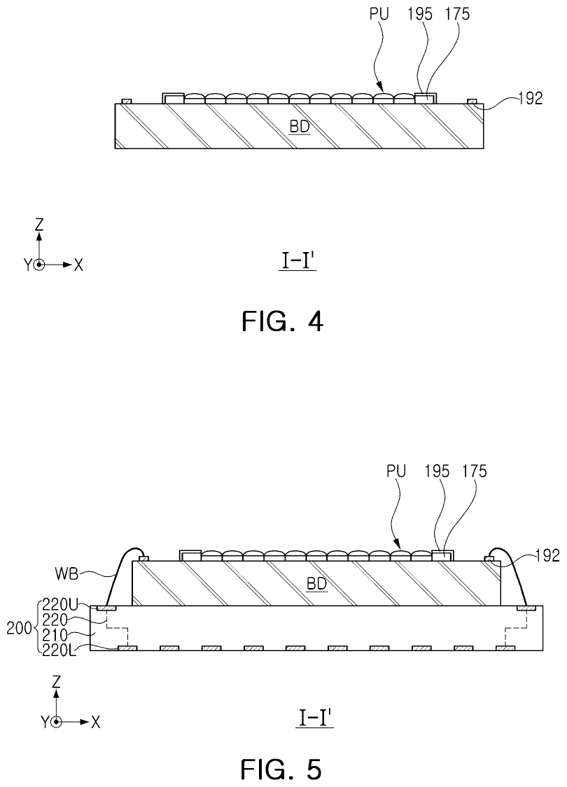

Referring to FIG. 6, an adhesive structure 400 may be attached to the body portion BD of the image sensor 100A.

The adhesive structure 400 may be disposed on an region adjacent to an outermost edge of the body portion BD. In some example embodiments, the adhesive structure 400 may be disposed within the pad region PAD, but the present inventive concept is not limited thereto. The adhesive structure 400 may extend into the optical black region OB. The adhesive structure 400 may be spaced apart from the light blocking filter pattern 175 and the capping layer 195 in the horizontal direction (for example, X-axis direction). The adhesive structure 400 may be, for example, a film layer formed of a DAF. As the adhesive structure 400 is attached to the connection pads 192 and the connection wires WB, at least a portion of the connection wires WB may be impregnated within the adhesive structure 400.

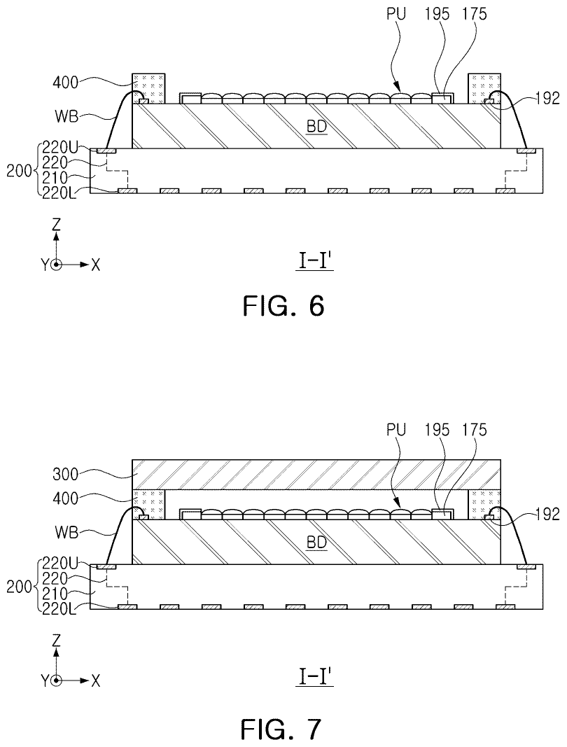

Referring to FIG. 7, a glass cover 300 may be attached to the adhesive structure 400.

The glass cover 300 may be attached to the image sensor 100A through the adhesive structure 400. In some example embodiments, an area of the glass cover 300 may be the same as an area of the body portion BD, but the present inventive concepts are not limited thereto. An uppermost end of the adhesive structure 400 may be positioned on a level higher than those of uppermost ends of the microlenses 190 and an uppermost end of the capping layer 195. As the glass cover 300 is disposed on the image sensor 100A and the adhesive structure 400, a space in a vertical direction (for example, Z-axis direction), may be formed between the glass cover 300 and the body portion BD, and the glass cover 300 may be spaced apart from the microlenses 190 and the capping layer 195 in the vertical direction (for example, Z-axis direction), thereby protecting the image sensor 100A and the microlenses 190 included therein.

Referring to FIGS. 1, 2A, and 2B together, connection bumps 500 may be disposed on the lower surface of the body portion BD through lower connection pads 220L. The semiconductor package 1000A according to the present example embodiments may be electrically connected to external devices through the connection bumps 500.

According to some example embodiments of the present inventive concepts, a light blocking filter pattern and a capping layer having a relatively high thermal expansion coefficient may be disposed on an upper portion of an image sensor to be spaced apart from an adhesive structure in a horizontal direction, thereby preventing or reducing in likelihood cracks that may occur on an upper thin film. Accordingly, a semiconductor package may have improved reliability.

While some example embodiments have been shown and described above, it will be apparent to those skilled in the art that modifications and variations could be made without departing from the scope of the present inventive concept as defined by the appended claims.

What is claimed is:

1. A semiconductor package comprising:
a package substrate;
an image sensor including a body portion on the package substrate, color filters on the body portion, microlenses respectively on the color filters, a light blocking filter pattern peripheral to the microlenses in a horizontal direction, a capping layer covering at least a portion of the light blocking filter pattern, an upper thin film covering at least a portion of the capping layer, and connection pads peripheral to the light blocking filter pattern in the horizontal direction;
a glass cover on the image sensor; and
an adhesive structure on the body portion spaced apart from the capping layer and the light blocking filter pattern in the horizontal direction, the adhesive structure covering at least a portion of the connection pads, between the image sensor and the glass cover.

2. The semiconductor package of claim 1, wherein
the image sensor has a pixel region including a plurality of unit pixels, an optical black region peripheral to the pixel region in the horizontal direction, and a pad region peripheral to the optical black region in the horizontal direction, and
in the pixel region, the image sensor further includes photoelectric conversion devices within the body portion.

3. The semiconductor package of claim 2, wherein the pad region has a connection via extending in a vertical direction from an upper surface of the body portion.

4. The semiconductor package of claim 2, further comprising:
connection wires electrically connected to the connection pads within the pad region.

5. The semiconductor package of claim 4, wherein the adhesive structure covers at least a portion of each of the connection wires.

6. The semiconductor package of claim 1, wherein the adhesive structure attaches the glass cover to the image sensor.

7. The semiconductor package of claim 1, wherein the capping layer covers a side surface, adjacent to the adhesive structure, among side surfaces of the light blocking filter pattern.

8. The semiconductor package of claim 1, wherein the adhesive structure is spaced apart from at least a portion of the upper thin film in the horizontal direction.

9. The semiconductor package of claim 1, wherein the capping layer includes a same material as that of the microlenses.

10. The semiconductor package of claim 1, wherein the light blocking filter pattern includes a same material as a material of the color filters.

11. The semiconductor package of claim 1, wherein the adhesive structure surrounds the light blocking filter pattern and the capping layer in a plan view.

12. The semiconductor package of claim 1, further comprising:
connection bumps on a lower surface of the body portion.

13. The semiconductor package of claim 1, wherein the upper thin film extends onto the microlenses.

14. A semiconductor package comprising:
a package substrate;
an image sensor on the package substrate, the image sensor having a first region and a second region peripheral to the first region in a horizontal direction;
a glass cover on the image sensor; and
an adhesive structure connecting the image sensor and the glass cover to each other,
wherein the image sensor includes a body portion, a stacked structure including a light blocking conductive layer and a protective layer on the body portion, a light blocking filter pattern on the stack structure within the first region, a capping layer on the light blocking filter pattern, and an upper thin film on the stack structure, and
the adhesive structure overlaps at least a portion of each of the stack structure and the upper thin film in a vertical direction within the second region.

15. The semiconductor package of claim 14, wherein the protective layer includes aluminum oxide (Al₂O₃).

16. The semiconductor package of claim 14, wherein the light blocking conductive layer includes tungsten (W).

17. The semiconductor package of claim 14, wherein the light blocking filter pattern and the capping layer include a material having a thermal expansion coefficient higher than a thermal expansion coefficient of silicon (Si).

18. The semiconductor package of claim 14, wherein an uppermost end of the adhesive structure is positioned on a level higher than a level of an uppermost end of the upper thin film.

19. A semiconductor package comprising:
a package substrate;
an image sensor on the package substrate, the image sensor including microlenses on a central portion thereof, a light blocking filter pattern peripheral to the microlenses in a horizontal direction, a capping layer surrounding at least a portion of the light blocking filter pattern, and an upper thin film surrounding at least a portion of the capping layer;
a glass cover spaced apart from the image sensor in a vertical direction; and
an adhesive structure between the image sensor and the glass cover, the adhesive structure having one side surface in contact with at least a portion of the upper thin film.

20. The semiconductor package of claim 19, wherein the adhesive structure is spaced apart from the light blocking filter pattern and the capping layer in the horizontal direction.
